(19) United States
(12) Patent Application Publication
(10) Pub. No.: US 2024/0215424 A1
(43) Pub. Date: Jun. 27, 2024

(54) DISPLAY PANEL AND MANUFACTURING METHOD THEREOF

(71) Applicant: Samsung Display Co., LTD., Yongin-si (KR)

(72) Inventor: Eun Byul JO, Yongin-si (KR)

(73) Assignee: Samsung Display Co., LTD., Yongin-si (KR)

(21) Appl. No.: 18/519,283

(22) Filed: Nov. 27, 2023

(30) Foreign Application Priority Data
Dec. 23, 2022 (KR) 10-2022-0183563

(51) Int. Cl. H10K 59/90; H10K 59/12; H10K 59/40; H10K 59/80

(52) U.S. Cl. CPC H10K 59/90; H10K 59/1201; H10K 59/40; H10K 59/80518

(57) ABSTRACT

A display panel including a display area and a non-display area, includes cell IDs disposed on a substrate in the non-display area and indicating identification information for identifying the display panel, and an insulating film disposed on the substrate and the cell IDs. The cell IDs include a first cell ID and a second cell ID disposed on the substrate in the non-display area, the first cell ID and the second cell ID are disposed in different areas, the first cell ID includes a single film structure including a first thin film layer, and the second cell ID includes a stacked structure of second thin film layers.

### CROSS REFERENCE TO RELATED APPLICATION(S)

This application claims priority to and the benefits of Korean Patent Application No. 10-2022-0183563 under 35 U.S.C. § 119, filed on Dec. 23, 2022, in the Korean Intellectual Property Office (KIPO), the entire contents of which are incorporated herein by reference.

### BACKGROUND

### 1. Technical Field

The disclosure relates to a display panel and a manufacturing method thereof.

### 2. Description of the Related Art

As information technology has developed, the importance of a display device, which is a connection medium between a user and information, has been highlighted. Accordingly, the use of display devices such as a liquid crystal display device, an organic light emitting display device, and the like has been increasing.

During a manufacturing process of the display device, multiple display panels may be included in a mother substrate and manufactured together, and may be separated from the mother substrate in a scribing process. A cell ID including unique information for distinguishing each display panel from other display panels may be provided in a non-display area of each of the display panels. The cell ID may be needed for analysis of whether or not a panel is defective during the manufacturing process of the display panel or for follow-up management.

In each manufacturing process of the display panel, since each display panel is identified by the cell ID, it may be difficult to grasp a process history of the display panel in case that a portion of the display panel in which the cell ID is formed is damaged or the cell ID is not recognized.

### SUMMARY

An embodiment of the disclosure has been made in an effort to provide a display panel and a manufacturing method thereof that may include at least two or more cell IDs including same information. Accordingly, in case that one cell ID is damaged or not recognized, a process history of a display panel may be grasped from another cell ID.

According to an embodiment of the disclosure, multiple cell IDs included in a display panel may have different structures. Accordingly, in each manufacturing process of the display panel, a cell ID having a readily recognizable structure may be selectively scanned.

According to an embodiment of the disclosure, a display panel including a display area and a non-display area may include cell IDs disposed on a substrate in the non-display area and indicating identification information for identifying the display panel, and an insulating film disposed on the substrate and the cell IDs. The cell IDs may include a first cell ID; and a second cell ID disposed on the substrate in the non-display area, the first cell ID and the second cell ID may be disposed in different areas, the first cell ID may include a single film structure including a first thin film layer, and the second cell ID may include a stacked structure of second thin film layers.

A material in the second thin film layers may have a higher reflectance with respect to light than a material in the first thin film layer.

At least one of the second thin film layers may include an opaque material.

The display panel may further include a pixel circuit layer disposed on the substrate in the display area. The pixel circuit layer may include a pixel circuit including a gate electrode, a source electrode, a drain electrode, and a semiconductor layer, the first thin film layer and the semiconductor layer may include a same material, the second thin film layers may include a third thin film layer and a fourth thin film layer, the third thin film layer and the semiconductor layer may include a same material, and the fourth thin film layer may include metallic material.

The fourth thin film layer may be provided on the third thin film layer.

The semiconductor layer may include polysilicon or amorphous silicon, and the fourth thin film layer may include molybdenum.

The fourth thin film layer and the gate electrode may include a same material.

The fourth thin film layer, the source electrode, and the drain electrode may include a same material.

The display panel may further include a pixel circuit layer on the substrate in the display area, and a display element layer disposed on the pixel circuit layer. The pixel circuit layer may include a pixel circuit including a gate electrode, a source electrode, a drain electrode, and a semiconductor layer. The display element layer may include a light emitting element including an anode electrode, a cathode electrode, and a light emitting layer provided between the anode electrode and the cathode electrode. The first thin film layer and the semiconductor layer may include a same material, the second thin film layers may include a third thin film layer and a fourth thin film layer, the third film layer and the semiconductor layer may include a same material, and the fourth thin film layer and the anode electrode may include a same material.

The fourth thin film layer and the anode electrode may have a three-layer stacked structure of ITO/AG/ITO.

According to an embodiment, a manufacturing method of a display panel including a display area and a non-display area may include providing cell IDs indicating identification information for identifying the display panel on a substrate in the non-display area, and providing an insulating film on the substrate and the cell IDs. The providing of the cell IDs may include providing a first cell ID on a portion of the substrate in the non-display area, and providing a second cell ID on another portion of the substate in the non-display area. The first cell ID may include a single film structure including a first thin film layer, and the second cell ID may include a stacked structure of second thin film layers.

A material in the second thin film layers may have a higher reflectance with respect to light than a material in the first thin film layer.

At least one of the second thin film layers may include an opaque material.

The manufacturing method of the display panel may further include providing a pixel circuit layer including a pixel circuit on the substrate in the display area. The providing of the pixel circuit layer may include providing a semiconductor layer on the substrate, providing a gate electrode on the semiconductor layer, and providing a source electrode and a drain electrode, each contacting a portion of the semiconductor layer. The first thin film layer and the semiconductor layer may include a same material, the second thin film layers may include a third thin film layer and a fourth thin film layer, the third thin film layer and the semiconductor layer may include a same material, and the fourth thin film layer may include a metallic material.

The providing of the cell IDs may include providing the fourth thin film layer on the third thin film layer after simultaneously providing the first thin film layer and the third thin film layer.

The semiconductor layer may include polysilicon or amorphous silicon, and the fourth thin film layer may include molybdenum.

The first thin film layer, the third thin film layer, and the semiconductor layer may be simultaneously provided, and the fourth thin film layer and the gate electrode may be simultaneously provided.

The first thin film layer, the third thin film layer, and the semiconductor layer may be simultaneously provided, and the fourth thin film layer, the source electrode, and drain electrode may be simultaneously provided.

The manufacturing method of the display panel may further include providing a pixel circuit layer including a pixel circuit on the substrate in the display area, and providing a display element layer on the pixel circuit layer. The providing of the pixel circuit layer may include providing a semiconductor layer on the substrate, providing a gate electrode on the semiconductor layer, and providing a source electrode and a drain electrode, each contacting a portion of the semiconductor layer. The providing of the display element layer may include providing an anode electrode on the pixel circuit layer, providing a light emitting layer contacting the anode electrode, and providing a cathode electrode on the light emitting layer. The first thin film layer and the semiconductor layer may include a same material, the second thin film layers may include a third thin film layer and a fourth thin film layer, the third thin film layer and the semiconductor layer may include a same material, and the fourth thin film layer may include a conductive material.

The first thin film layer, the third thin film layer, and the semiconductor layer may be simultaneously provided, and the fourth thin film layer and the anode electrode may be simultaneously provided.

According to an embodiment of the disclosure, in case that a cell ID among multiple cell IDs included in a display panel is damaged or is not recognized, a process history of the display panel may be grasped through another cell ID.

According to an embodiment of the disclosure, in each manufacturing process of the display panel, among a plurality of cell IDs included in the display panel, a cell ID having a readily recognizable structure may be selectively scanned.

### BRIEF DESCRIPTION OF THE DRAWINGS

FIG. 1 is a schematic perspective view of a display device according to an embodiment.

FIG. 2 is a schematic cross-sectional view of the display device of FIG. 1.

FIG. 3 is a schematic plan view of a display panel of FIG. 2.

FIG. 4 is a schematic cross-sectional view of a display panel of FIG. 2.

FIG. 5 is a schematic cross-sectional view of a portion of the display panel of FIG. 2.

FIG. 6A is a schematic plan view illustrating a cell ID included in a display panel.

FIG. 6B is a schematic cross-sectional view taken along line I-I′ of FIG. 6A.

FIG. 7A and FIG. 7B are schematic cross-sectional views illustrating how a cell ID is scanned.

FIG. 8A is a schematic plan view illustrating a display panel and a cell ID included in the display panel according to an embodiment.

FIG. 8B is a schematic cross-sectional view taken along line II-II′ of FIG. 8A.

FIG. 9A is a schematic cross-sectional view illustrating a process in which a first cell ID is scanned in an embodiment.

FIG. 9B is a schematic cross-sectional view illustrating a process in which a second cell ID is scanned in an embodiment.

FIG. 10A is a schematic plan view of a display panel manufactured by manufacturing method of the display panel according to an embodiment.

FIG. 10B is a schematic cross-sectional view taken along line III-III′ of FIG. 10A.

FIG. 11 is a schematic cross-sectional view illustrating a manufacturing process of a display panel according to another embodiment.

FIG. 12 is a schematic cross-sectional view illustrating a manufacturing process of a display panel according to another embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Since the disclosure may be variously modified and have various forms, embodiments will be illustrated and described in detail in the following. However, by no means restricts the disclosure to the specific embodiments, and it is to be understood as embracing all included in the spirit and scope of the disclosure changes, equivalents, and substitutes.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

When an embodiment may be implemented differently, a specific process order may be performed differently from the described order. For example, two consecutively described processes may be performed substantially at the same time or performed in an order opposite to the described order. Like reference numerals are used for like constituent elements in describing each drawing.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. In the accompanying drawings, the dimensions of the structure are exaggerated and shown for clarity of the disclosure.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Terms such as “first,” “second,” and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the disclosure. Moreover, the terminology used herein is for the purpose of describing particular embodiments and is not intended to be limiting. As used herein, the singular forms, “a,” “an,” and “the” are intended to include the plural forms as well, unless the context clearly indicates otherwise.

The first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ.

In the application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that when an element such as a layer, film, region, area, or substrate is referred to as being “on” another element, it can be directly on the other element or intervening elements may also be present. In the specification, when an element of a layer, film, region, area, plate, or the like is referred to as being formed “on” another element, the formed direction is not limited to an upper direction but includes a lateral or lower direction. In contrast, when an element of a layer, film, region, area, plate, or the like is referred to as being “below” another element, it may be directly below the other element, or intervening elements may be present.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a plane or on a plane” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some example embodiments may be physically separated into two or more interacting and discrete blocks, units, and/or modules without departing from the scope of the disclosure. Further, the blocks, units, and/or modules of some example embodiments may be physically combined into more complex blocks, units, and/or modules without departing from the scope of the disclosure.

It is to be understood that, in the application, when it is described for one constituent element (for example, a first constituent element) to be (functionally or communicatively) “coupled or connected with/to” another constituent element (for example, a second constituent element), the one constituent element may be directly coupled or connected with/to the another constituent element, or may be coupled or connected with/to through the other constituent element (for example, a third constituent element). In contrast, it is to be understood that when it is described for one constituent element (for example, a first constituent element) to be “directly coupled or connected with/to” another constituent element (for example, a second constituent element), there is no other constituent element (for example, a third constituent element) between the one constituent element and the another constituent element.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, with reference to accompanying drawings, embodiments of the disclosure and others required for those skilled in the art to understand the contents of the disclosure will be described in more detail. In the description below, singular forms are to include plural forms unless the context clearly indicates only the singular.

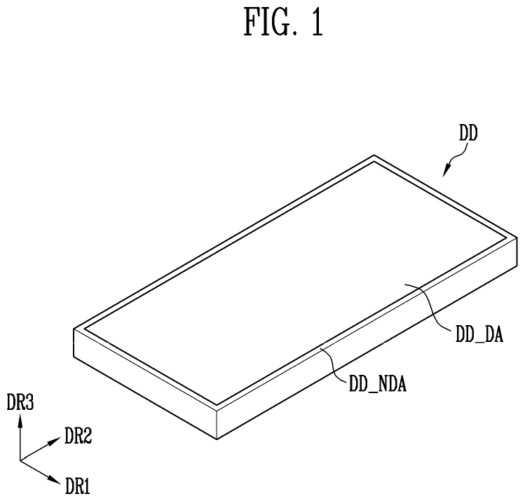

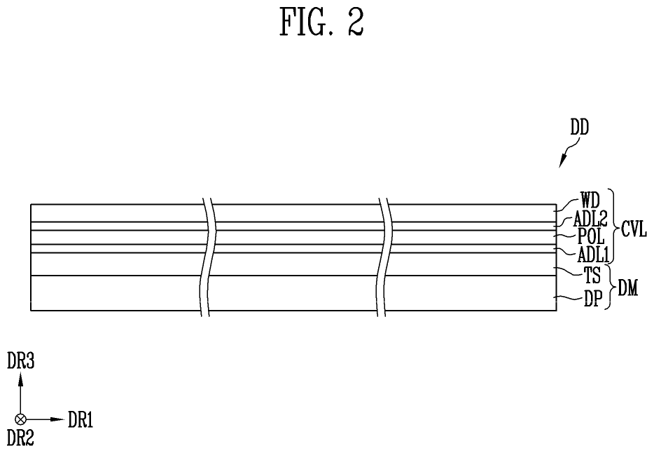

FIG. 1 is a schematic perspective view of a display device DD according to an embodiment, and FIG. 2 is a schematic cross-sectional view of the display device DD of FIG. 1.

Referring to FIG. 1 and FIG. 2, the display device DD may include a display module DM and a cover layer CVL.

The display device DD may be provided in various shapes, and for example, may be provided in a rectangular shape having two pairs of sides parallel to each other in a plan view, but the disclosure is not limited thereto. In case that the display device DD is provided in the rectangular shape, sides of a pair may be provided to be longer than sides of another pair. For better understanding and ease of description, a display device DD having a rectangular shape with a pair of long sides and a pair of short sides is illustrated, and an extending direction of the long side is indicated as a second direction DR2, an extending direction of the short side is indicated as a first direction DR1, and a thickness direction of the display device DD is indicated as a third direction DR3 in FIG. 1. In an embodiment, in the display device DD provided in a rectangular shape, a corner portion at which a long side and a short side contact each other may have a round shape.

At least a portion of the display device DD may have flexibility, and the display device DD may be foldable at the portion having the flexibility, but the disclosure is not limited thereto.

The display device DD may include a display area DD_DA for displaying an image and a non-display area DD_NDA provided in at least one side of the display area DD_DA (or adjacent to the display area DD_DA). The non-display area DD_NDA may be an area in which an image is not displayed.

In an embodiment, the display device DD may include a sensing area and a non-sensing area. The display device DD not only may display an image through the sensing area, but also may detect an input made on a display surface (or input surface) or may detect light incident on a display surface (or input surface). The non-sensing area may surround the sensing area (or be disposed adjacent to the sensing area), but this is merely an example, but the disclosure is not limited thereto. In an embodiment, a portion of the display area DD_DA may correspond to the sensing area.

The display module DM may include a display panel DP and a touch sensor TS.

The touch sensor TS may be disposed (e.g., directly disposed) on the display panel DP, or may be disposed on the display panel DP with a separate layer such as an adhesive layer, a substrate, or the like interposed between the display panel DP and the touch sensor TS.

The display panel DP may display an image. As the display panel DP, a self-luminous display panel, such as an organic light emitting display panel (OLED panel) or the like, may be used. As the display panel DP, a non-light emitting display panel such as a liquid crystal display panel (LCD panel), an electro-phoretic display panel (EPD panel), an electro-wetting display panel (EWD panel), or the like may be used. In case that the non-light emitting display panel is used as the display panel DP, the display device DD may be provided with a light emitting device that supplies light to the display panel DP.

The touch sensor TS may be disposed on a surface on which an image of the display panel DP is emitted to receive a user's touch input. The touch sensor TS may recognize a touch event on the display device DD by a user's hand, a separate input member, or the like. The touch sensor TS may recognize a touch event with a capacitance method.

The touch sensor TS may sense the touch input by using a mutual capacitance method or a self-capacitance method.

The cover layer CVL may be disposed on the display module DM.

The cover layer CVL may include a polarizing film POL, first and second adhesive layers ADL1 and ADL2, and a window WD.

The polarizing film POL may be provided between the touch sensor TS and the window WD, and may polarize light emitted from the display panel DP along a polarization axis. The polarizing film POL may be coupled with the display module DM (or the touch sensor TS) by the first adhesive layer ADL1.

The first adhesive layer ADL1 may include a pressure sensitive adhesive that acts as an adhesive material in case that pressure to an adhesive surface is applied to the first adhesive layer ADL1. In case that the first adhesive layer ADL1 includes a pressure sensitive adhesive, the first adhesive layer ADL1 may be attached to the adhesive surface with pressure without separate heat treatment or UV treatment at room temperature.

The window WD for protecting an exposed surface of the display module DM may be provided on the polarizing film POL. The window WD may protect components disposed under the window WD (for example, the display module DM) from an external impact, and may provide an input surface and/or a display surface to a user. The window WD may be coupled with the display module DM by using the second adhesive layer ADL2. The second adhesive layer ADL2 may include an optically clear adhesive or the like.

The window WD may have a multi-layered structure including a glass substrate, a plastic film, a plastic substrate, the like, or a combination thereof. The multi-layered structure may be formed through a continuous process, an adhesive process using an adhesive layer, or the like. The window WD may be entirely or partially flexible.

In the following embodiment, for better understanding and ease of description, a horizontal direction in a plan view is indicated as the first direction DR1, a vertical direction in a plan view is indicated as the second direction DR2, and a vertical direction in a cross-sectional view is indicated as the third direction DR3.

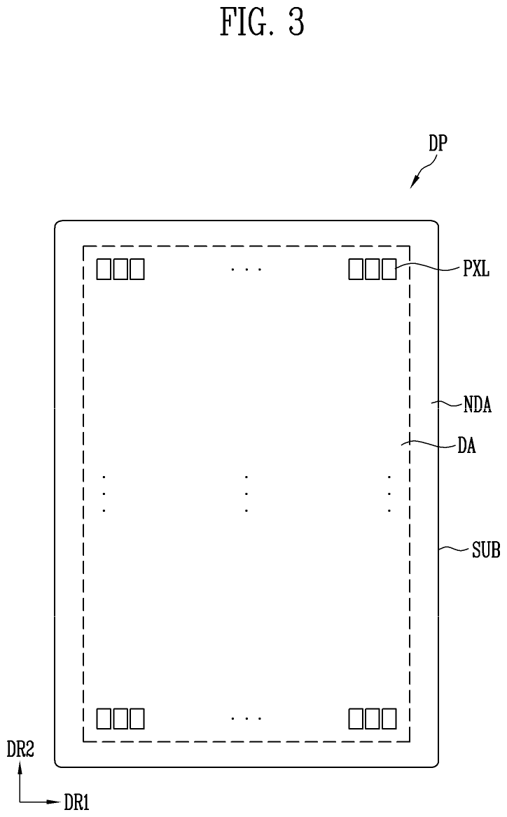

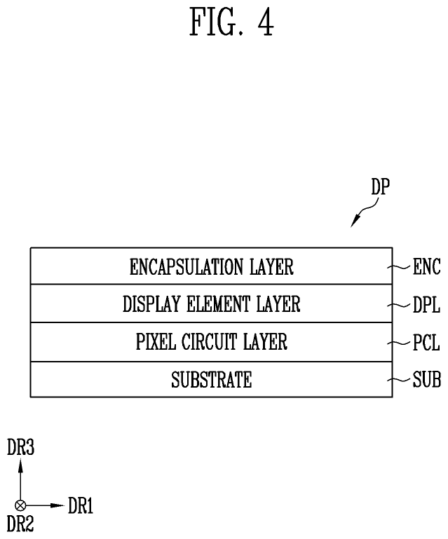

FIG. 3 is a schematic plan view of the display panel DP of FIG. 2, and FIG. 4 is a schematic cross-sectional view of the display panel DP of FIG. 2.

Referring to FIG. 1 to FIG. 4, the display panel DP according to an embodiment may include a substrate SUB and multiple pixels PXL provided on the substrate SUB.

The substrate SUB may be configured of one area having a rectangular shape, for example, an approximately rectangular shape in a plan view. However, the number of areas provided in the substrate SUB is not limited thereto, and the substrate SUB may have a different shape depending on the area provided in the substrate SUB.

The substrate SUB may be made of an insulating material such as glass, a resin, or the like. The substrate SUB may be made of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material included in the substrate SUB is not limited to the above-described embodiment.

The substrate SUB may include a display area DA and a non-display area NDA.

The display area DA may be an area in which the pixels PXL are provided to display an image, and the non-display area NDA may be an area in which the pixels PXL are not provided, and no image is displayed.

The display area DA of the display panel DP may correspond to the display area DD_DA of the display device DD, and the non-display area NDA of the display panel DP may correspond to the non-display area DD_NDA of the display device DD.

A driver for driving the pixels PXL and some of wires (for example, fan-out lines) connecting the pixels PXL and the driver may be provided in the non-display area NDA. The non-display area NDA may correspond to a bezel area of the display device DD.

The pixels PXL may be provided in the display area DA of the substrate SUB. Each of the pixels PXL may be a minimum unit that displays an image. The pixels PXL may include light emitting elements that emit white light and/or color light. Each of the pixels PXL may emit light of a color such as red, green, and blue, but the disclosure is not limited thereto. In an embodiment, each of the pixels PXL may emit light of a color such as cyan, magenta, yellow, and the like.

The pixels PXL may be disposed in a matrix form along rows (or pixel rows) in the first direction DR1 and columns (or pixel columns) in the second direction DR2 intersecting the first direction DR1 in a plan view. However, an arrangement of the pixels PXL is not particularly limited thereto, and the pixels PXL may be disposed in various forms. In FIG. 3, the pixels PXL are shown to have a rectangular shape in a plan view, but the disclosure is not limited thereto, and the pixels PXL may have various shapes. In case that multiple pixels PXL are provided, the multiple pixels PXL may be provided to have different areas (or sizes) in a plan view. For example, in case that the pixels PXL have different colors of emitted light, the pixels PXL for each color may be provided in different areas (or sizes) or in different shapes in a plan view.

The driver may provide a signal and power to each of the pixels PXL through a wire to control driving of the pixels PXL.

The display panel DP, as shown in FIG. 4, may include a pixel circuit layer PCL, a display element layer DPL, and an encapsulation layer ENC that are sequentially disposed on the substrate SUB.

The pixel circuit layer PCL may be provided on the substrate SUB, and may include multiple transistors and multiple signal lines connected to the transistors. For example, each transistor may have a structure in which a semiconductor layer, a gate electrode, a first terminal, and a second terminal are sequentially stacked with an insulating layer interposed between the semiconductor layer, the gate electrode, the first terminal, and the second terminal. The semiconductor layer may include amorphous silicon, poly silicon, low temperature poly silicon, an organic semiconductor, an oxide semiconductor, and/or the like. The gate electrode, the first terminal, and the second terminal may include at least one of aluminum (Al), copper (Cu), titanium (Ti), molybdenum (Mo), and the like, but the disclosure is not limited thereto. The pixel circuit layer PCL may include at least one or more insulating layers.

The display element layer DPL may be disposed on the pixel circuit layer PCL. The display element layer DPL may include a light emitting element LD that emits light. The light emitting element LD may be, for example, an organic light emitting diode, but the disclosure is not limited thereto. In an embodiment, the light emitting element LD may be an inorganic light emitting element including an inorganic light emitting material or a light emitting element that emits light by changing a wavelength of light emitted by using a quantum dot.

The encapsulation layer ENC may be disposed on the display element layer DPL. The encapsulation layer ENC may be an encapsulation substrate or a multi-layered encapsulation film. In case that the encapsulation layer ENC is in a form of the encapsulation film, the encapsulation layer ENC may include an inorganic film and/or an organic film. For example, the encapsulation layer ENC may have a structure in which an inorganic film, an organic film, and an inorganic film are sequentially stacked. The encapsulation layer ENC may prevent external air and/or moisture from penetrating into the display element layer DPL and the pixel circuit layer PCL.

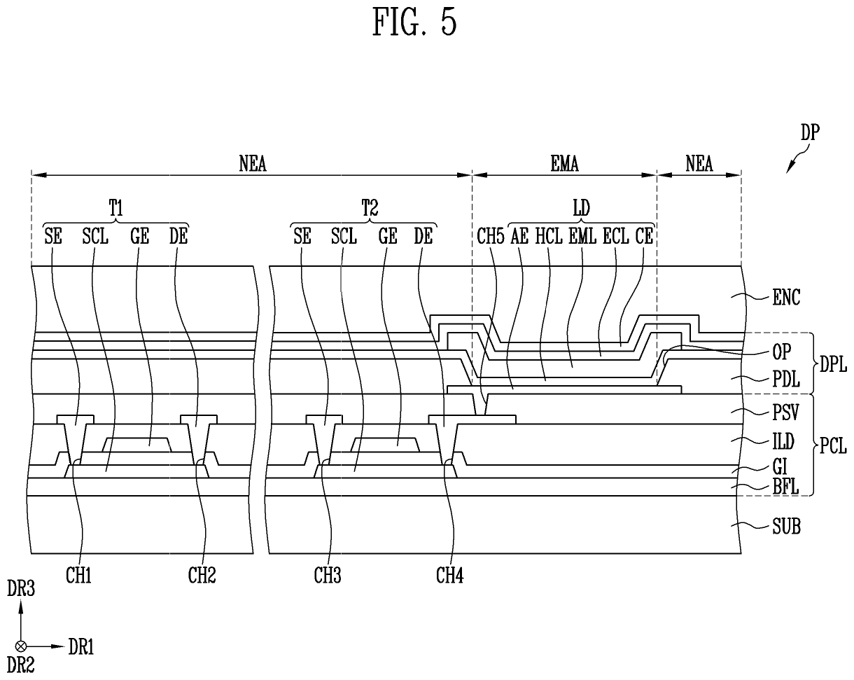

FIG. 5 is a schematic cross-sectional view of a portion of the display panel DP of FIG. 2.

Referring to FIG. 1 to FIG. 5, the display panel DP may include the substrate SUB, the pixel circuit layer PCL, the display element layer DPL, and the encapsulation layer ENC.

The substrate SUB may include an insulating material such as glass, organic polymer, crystal, or the like. The substrate SUB may be made of a flexible material to be bendable or foldable, and may have a single-layered structure or a multi-layered structure.

The pixel circuit layer PCL may include a buffer layer BFL, a gate insulating layer GI, an interlayer insulating layer ILD, and a passivation layer PSV that are sequentially stacked on the substrate SUB in the third direction DR3.

The buffer layer BFL may be disposed on an entire area of the substrate SUB. The buffer layer BFL may prevent impurities from spreading to first and second transistors T1 and T2. The buffer layer BFL may be an inorganic insulating film including an inorganic material. The buffer layer BFL may include at least one of a silicon nitride (SiNₓ), a silicon oxide (SiOₓ), a silicon oxynitride (SiOₓN_{y}), and an aluminum oxide (AlOₓ). The buffer layer BFL may be provided as a single layer or a multilayer of at least double layers or more. In case that the buffer layer BFL is provided (or formed) as multiple layers, each of layers of the buffer layer BFL may be made of a same material or different materials. The buffer layer BFL may be omitted depending on the material, a process condition, or the like of the substrate SUB.

The gate insulating layer GI may be disposed on an entire area of the buffer layer BFL. The gate insulating layer GI and the above-described buffer layer BFL may include a same material. The gate insulating layer GI may include a material suitable (or selected) from materials described as constituent materials of the buffer layer BFL. For example, the gate insulating layer GI may be an inorganic insulating film including an inorganic material.

The interlayer insulating layer ILD may be disposed and/or provided on an entire area of the gate insulating layer GI. The interlayer insulating layer ILD and the gate insulating layer GI may include a same material. The interlayer insulating layer ILD may include one or more materials suitable (or selected) from the materials illustrated as constituent materials of the gate insulating layer GI.

The passivation layer PSV may be provided and/or disposed on an entire area of the interlayer insulating layer ILD. The passivation layer PSV may be an inorganic insulating film including an inorganic material or an organic insulating film including an organic material. The inorganic insulating film may include, for example, at least one of a silicon nitride (SiNₓ), a silicon oxide (SiOₓ), a silicon oxynitride (SiOₓN_{y}), and an aluminum oxide (AlOₓ). The organic insulating film may be, for example, at least one of a polyacrylate resin, an epoxy resin, a phenolic resin, a polyamide resin, a polyimide rein, an unsaturated polyester resin, a poly-phenylene ether resin, a poly-phenylene sulfide resin, and a benzocyclobutene resin.

Each of the first and second transistors T1 and T2 may include a semiconductor layer SCL, a gate electrode GE, a source electrode SE, and a drain electrode DE.

The semiconductor layer SCL of each of the first and second transistors T1 and T2 may be disposed on the buffer layer BFL. The semiconductor layer SCL may include source and drain areas respectively contacting the source electrode SE and the drain electrode DE. An area between the source area and the drain area may be a channel area.

The semiconductor layer SCL may be a semiconductor pattern made of polysilicon, amorphous silicon, an oxide semiconductor, or the like. The channel area may be an intrinsic semiconductor pattern in which no impurity is doped. An impurity such as an n-type impurity, a p-type impurity, or other metals may be used as the impurity. The source and drain areas may be a semiconductor pattern doped with an impurity.

The gate electrode GE of each of the first and second transistors T1 and T2 may be disposed on the gate insulating layer GI, and may overlap the corresponding semiconductor layer SCL in a plan view.

The source electrode SE of each of the first and second transistors T1 and T2 may be disposed on the interlayer insulating layer ILD and contact the source area of the corresponding semiconductor layer SCL through a contact hole penetrating the interlayer insulating layer ILD and the gate insulating layer GI. For example, the source electrode SE of the first transistor T1 may contact the source area of the corresponding semiconductor layer SCL through a first contact hole CH1 penetrating the interlayer insulating layer ILD and the gate insulating layer GI, and the source electrode SE of the second transistor T2 may contact the source area of the corresponding semiconductor layer SCL through a third contact hole CH3 penetrating the interlayer insulating layer ILD and the gate insulating layer GI.

The drain electrode DE of each of the first and second transistors T1 and T2 may be disposed on the interlayer insulating layer ILD and contact the drain area of the corresponding semiconductor layer SCL through a contact hole penetrating the interlayer insulating layer ILD and the gate insulating layer GI. For example, the drain electrode DE of the first transistor T1 may contact the drain area of the corresponding semiconductor layer SCL through a second contact hole CH2 penetrating the interlayer insulating layer ILD and the gate insulating layer GI, and the drain electrode DE of the second transistor T2 may contact the drain area of the corresponding semiconductor layer SCL through a fourth contact hole CH4 penetrating the interlayer insulating layer ILD and the gate insulating layer GI.

The passivation layer PSV may be disposed on an entire area of the first and second transistors T1 and T2 and cover the first and second transistors T1 and T2. The passivation layer PSV may include a fifth contact hole CH5 exposing a portion of the drain electrode DE of the second transistor T2 to an outside.

The display element layer DPL including a light emitting element LD may be disposed on the passivation layer PSV.

The light emitting element LD may include first and second electrodes AE and CE, and a light emitting layer EML provided between the two electrodes AE and CE (e.g., the first electrode AE and the second electrode CE). One of the first and second electrodes AE and CE may be an anode, and another one of the first and second electrodes AE and CE may be a cathode. For example, the first electrode AE may be an anode, and the second electrode CE may be a cathode. In case that the light emitting element LD is a top light emitting type of organic light emitting element, the first electrode AE may be a reflective electrode, and the second electrode CE may be a transmissive electrode. For convenience of description, a light emitting element LD of a top light emitting type of organic light emitting element and the first electrode AE as an anode will be described as an embodiment, but the disclosure is not limited thereto.

The first electrode AE may be electrically connected to the drain electrode DE of the second transistor T2 through the fifth contact hole CH5 penetrating the passivation layer PSV. The first electrode AE may include a reflective film (not shown) reflecting light and a transparent conductive film (not shown) disposed above or below the reflective film. At least one of the transparent conductive film and the reflective film may be electrically connected to the drain electrode DE of the second transistor T2.

The display element layer DPL may further include a pixel defining film PDL having an opening OP exposing a portion of the first electrode AE, for example, an upper surface of the first electrode AE.

Each of the pixels PXL provided on the display panel DP may be disposed in the display area DA. In an embodiment, the pixel may include a light emitting area EMA and a non-light emitting area NEA adjacent to the light emitting area EMA. The non-light emitting area NEA may surround the light emitting area EMA. In an embodiment, the light emitting area EMA may correspond to the portion of the first electrode AE exposed by the opening OP of the pixel defining film PDL.

The display element layer DPL may include a hole control layer HCL and an electron control layer ECL.

The hole control layer HCL may be commonly disposed in the light emitting area EMA and the non-light emitting area NEA. Although not separately shown, a common layer such as the hole control layer HCL and the electron control layer ECL may be commonly disposed in pixels PXL.

The light emitting layer EML may be disposed on the hole control layer HCL. The light emitting layer EML may be disposed in an area corresponding to the opening OP. The light emitting layer EML may be provided separately in each of the pixels PXL. The light emitting layer EML may include an organic material and/or an inorganic material. In FIG. 5, a patterned light emitting layer EML is illustrated as an embodiment. However, the disclosure is not limited thereto, and the light emitting layer EML may be commonly provided in the pixels PXL in another embodiment. A color of light generated by the light emitting layer EML may be one of red, green, blue, and white, but the disclosure is not limited thereto. For example, the color of light generated by the emission layer EML may be one of magenta, cyan, yellow, and the like.

The electron control layer ECL may be provided on the light emitting layer EML. The electron control layer ECL may be commonly provided in the pixels PXL, and may serve to inject and/or transport electrons to the light emitting layer EML.

The second electrode CE may be provided on the electron control layer ECL. The second electrode CE may be commonly provided in the pixels PXL.

The encapsulation layer ENC covering the second electrode CE may be provided on the second electrode CE.

The encapsulation layer ENC may be provided as a single layer or a multi-layer. The encapsulation layer ENC may include multiple insulating films covering the light emitting element LD. For example, the encapsulation layer ENC may include at least one inorganic film and at least one organic film. For example, the encapsulation layer ENC may have a structure in which an inorganic film and an organic film are alternately stacked each other. In an embodiment, the encapsulation layer ENC may be an encapsulation substrate that is disposed on the light emitting element LD and bonded to the substrate SUB by a sealant.

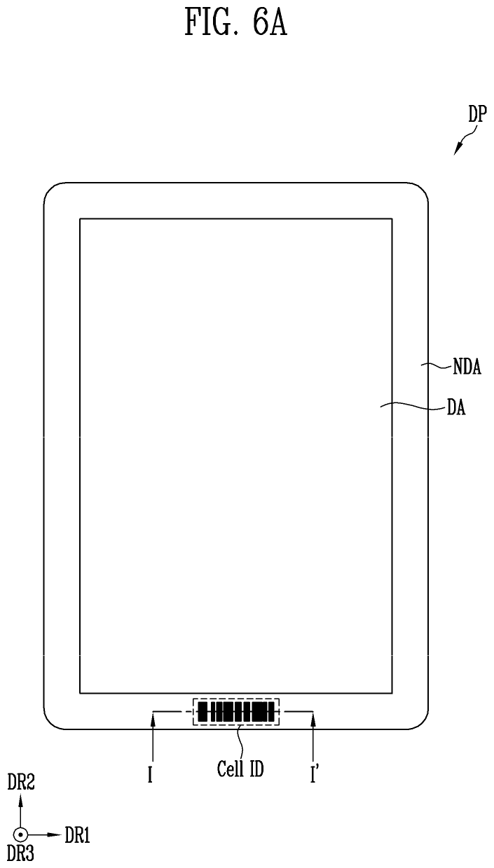

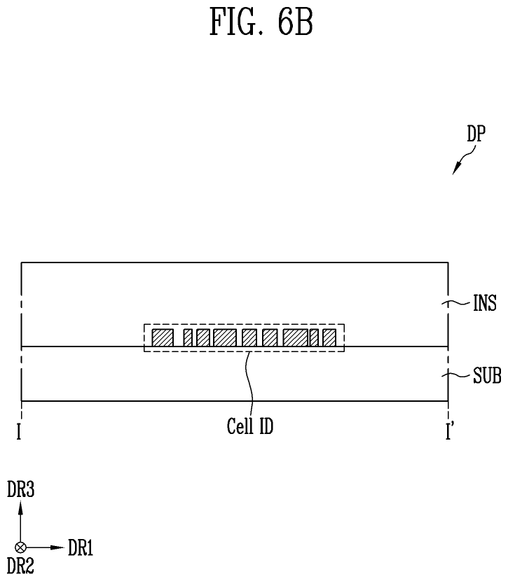

FIG. 6A is a schematic plan view illustrating a cell ID (Cell ID) included in a display panel DP.

Referring to FIG. 6A, the display panel DP may include the display area DA and the non-display area NDA. The display area DA may be an area an image is displayed on the display panel DP, and the non-display area NDA may be an area other than the display area DA.

A cell ID (Cell ID) may be provided on the display panel DP in the non-display area NDA. The cell ID (Cell ID) may include information for distinguishing a display panel DP from other display panels during a manufacturing process of the display panel DP or after the display panel DP is manufactured. The manufacturing process of each display panel DP may be managed based on the cell ID (Cell ID) assigned to each display panel DP. The cell ID (Cell ID) may be provided in the non-display area NDA of each display panel DP during the manufacturing process of the display panel DP. For example, the cell ID (Cell ID) of the display panel DP may be provided in the non-display area NDA of the display panel DP at a beginning of the manufacturing process of the display panel DP.

In processes performed after the cell ID (Cell ID) is provided on the display panel DP, the process history of the display panel DP may be recorded along with the unique cell ID (Cell ID) of the display panel DP. Remaining processes of the display panel DP may be sequentially performed based on the recorded process history. For each manufacturing process of the display panel DP, the cell ID (Cell ID) of the display panel DP may be scanned by using a separate scanner to identify the process history of the display panel DP.

FIG. 6B is a schematic cross-sectional view taken along line I-I′ of FIG. 6A.

Referring to FIG. 6B, the cell ID (Cell ID) may be provided on the substrate SUB of the display panel DP. In FIG. 6B, the cell ID (Cell ID) may have a single thin film layered structure. For example, the cell ID (Cell ID) may be made of a semiconductor material, a metallic material, or the like. For example, the cell ID (Cell ID) may be made of polysilicon, amorphous silicon, an oxide semiconductor, or the like. For example, the cell ID (Cell ID) may include at least one of molybdenum (Mo), aluminum (Al), chromium (Cr), gold (Au), titanium (Ti), nickel (Ni), neodymium (Nd), copper (Cu), and the like.

After the cell ID (Cell ID) is provided on an area of the substrate SUB, an insulating layer INS may be provided on the substrate SUB and the cell ID (Cell ID).

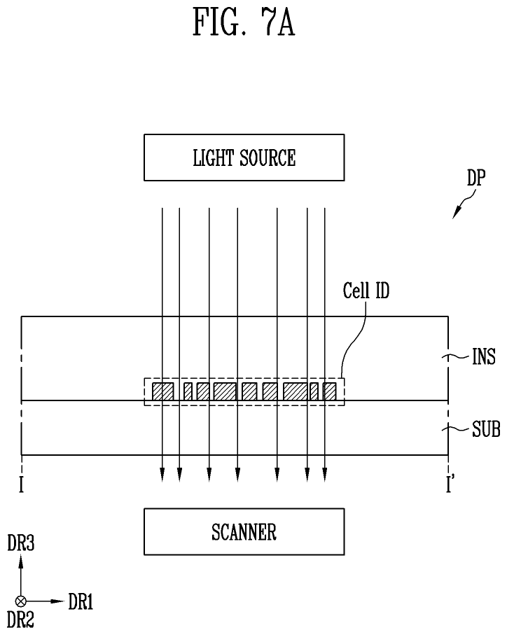

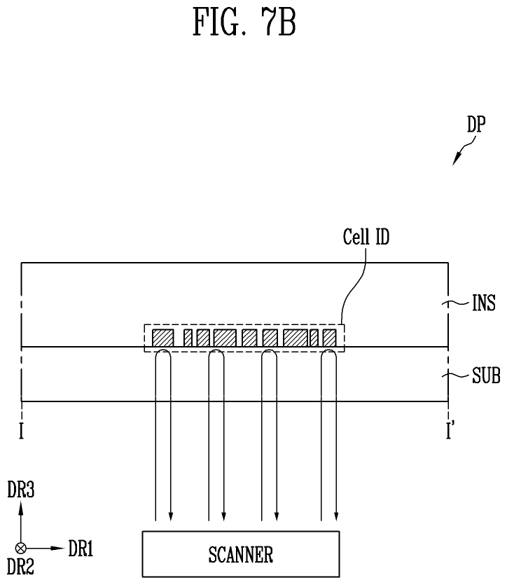

FIG. 7A and FIG. 7B are schematic cross-sectional views illustrating how the cell ID (Cell ID) is scanned.

Referring to FIG. 7A, the cell ID (Cell ID) of the display panel DP may be identified by scanning light passing through the area on which the cell ID (Cell ID) is provided. Light of a specific wavelength from a light source spaced apart from the upper surface of the display panel DP by a distance (e.g., a predetermined distance) in the vertical third direction DR3 may be irradiated onto the upper surface of the display panel DP. Since the substrate SUB and the insulating layer INS are made of a transparent material, the light irradiated on the upper surface of the display panel DP may transmit through the display panel DP. The light transmitted through the display panel DP may be scanned by a scanner spaced apart from the lower surface of the display panel DP by a distance (e.g., a predetermined distance) in a direction opposite to the third direction DR3.

Referring to FIG. 7B, the cell ID (Cell ID) of the display panel DP may be identified by scanning light reflected from an area on which the cell ID (Cell ID) is provided. Light of a specific wavelength from a light source (not shown) spaced apart from the lower surface of the display panel DP by a distance (e.g., a predetermined distance) in a direction opposite to the third direction DR3 may be radiated onto the lower surface of the display panel DP. The light irradiated onto the lower surface of the display panel DP may be reflected from the cell ID (Cell ID) provided on the substrate SUB of the display panel DP. The light reflected from the cell ID (Cell ID) may be scanned by a scanner spaced apart from the lower surface of the display panel DP by a distance (e.g., a predetermined distance) in a direction opposite to the third direction DR3.

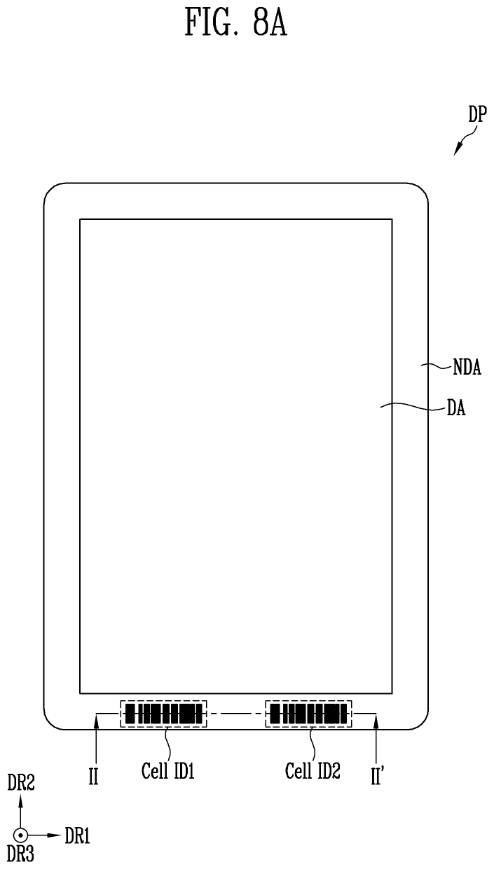

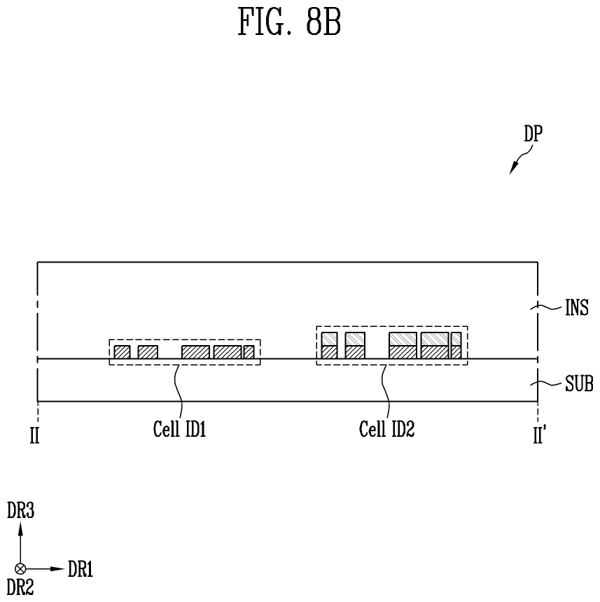

FIG. 8A is a schematic plan view illustrating a display panel DP and a cell ID (Cell ID) included in the display panel DP according to an embodiment.

Referring to FIG. 8A, multiple cell IDs (Cell ID1 and Cell ID2) may be provided on the display panel DP in the non-display area NDA according to an embodiment. For example, a first cell ID (Cell ID1) and a second cell ID (Cell ID2) may be provided in the non-display area NDA of the display panel DP. The first cell ID (Cell ID1) and the second cell ID (Cell ID2) may display information on the same display panel DP. Since the cell ID (Cell ID) displays information of the display panel DP on which the cell ID (Cell ID) is provided, and the first cell ID (Cell ID1) and the second cell ID (Cell ID2) are provided on the same display panel DP, information indicated by the first cell ID (Cell ID1) and the second cell ID (Cell ID2) may be the same. Accordingly, in a plan view, the first cell ID (Cell ID1) and the second cell ID (Cell ID2) may have a same shape.

In an embodiment, the cell IDs (Cell ID1 and Cell ID2) may be a barcode or a quick response (QR) code corresponding to the display panel DP on which the cell IDs (Cell ID1 and Cell ID2) are provided. In another embodiment, the cell IDs (Cell ID1 and Cell ID2) may be a specific character string, a specific number sequence, or a combination of the specific character string and the specific number sequence corresponding to the display panel DP on which the cell IDs (Cell ID1 and Cell ID2) are provided. Each of the cell IDs (Cell ID1 and Cell ID2) may be scanned by a barcode scanner, a QR code scanner, an optical character reader (OCR), the like, or a combination thereof.

The display panel DP according to an embodiment may include multiple cell IDs (Cell ID1 and Cell ID2) indicating a same information. According to an embodiment, in case that a cell ID (for example, Cell ID1) is damaged or not recognized, the display panel DP may be identified by scanning another cell ID (for example, Cell ID2). Accordingly, a recognition rate of the cell ID (Cell ID) may be improved in the manufacturing process of the display panel DP.

FIG. 8B is a schematic cross-sectional view taken along line II-II′ of FIG. 8A.

Referring to FIG. 8B, the first cell ID (Cell ID1) and the second cell ID (Cell ID2) may have different structures. For example, the first cell ID (Cell ID1) and the second cell ID (Cell ID2) may have the same shape in a plan view, but in a cross-sectional view in the second direction DR2 or in the first direction DR1, a structure of the first cell ID (Cell ID1) and a structure of the second cell ID (Cell ID2) may be different from each other.

In an embodiment, the first cell ID (Cell ID1) may have a single film structure including a thin film layer (e.g., a first thin film layer), and the second cell ID (Cell ID2) may have a stacked structure of thin film layers. The thin film layers of the stacked structure included in the second cell ID (Cell ID2) may include a material having a higher reflectance for light than the first thin film layer of the single film structure included in the first cell ID (Cell ID1). For example, at least one of the thin film layers included in the second cell ID (Cell ID2) may include an opaque material. For example, the thin film layer included in the first cell ID (Cell ID1) may include a semiconductor material, and the thin film layers included in the second cell ID (Cell ID2) may include a metallic material (in addition to the semiconductor material). For example, one of the thin film layers included in the second cell ID (Cell ID2) may include a semiconductor material, and another one of the thin film layers included in the second cell ID (Cell ID2) may include a metallic material. Among the thin film layers included in the second cell ID (Cell ID2), the thin film layer including the metallic material may be provided on the thin film layer including the semiconductor material.

In an embodiment, the semiconductor material included in the thin film layer of the first cell ID (Cell ID1) and a thin film layer of the second cell ID (Cell ID2) may be polysilicon, amorphous silicon, the like, or a combination thereof. The metallic material included in another thin film layer included in the second cell ID (Cell ID2) may include one of molybdenum (Mo), aluminum (Al), chromium (Cr), gold (Au), titanium (Ti), nickel (Ni), neodymium (Nd), copper (Cu), and the like. The metallic material included in the another thin film layer included in the second cell ID (Cell ID2) may include an alloy of two or more metals of molybdenum (Mo), aluminum (Al), chromium (Cr), gold (Au), titanium (Ti), nickel (Ni), neodymium (Nd), copper (Cu), and the like.

In an embodiment, the thin film layers included in the second cell ID (Cell ID2) may include thin film layers having a structure in which ITO and other metals are stacked with each other. For example, the second cell ID (Cell ID2) may include a three-layer stacked structure of ITO/AG/ITO.

In the manufacturing process of the display panel DP including multiple processes, a process of scanning the first cell ID (Cell ID1) and a process of scanning the second cell ID (Cell ID2) may be different from each other. For example, in case that first to twentieth processes are sequentially performed to manufacture a display panel DP, the first cell ID (Cell ID1) may be scanned in the first to tenth processes, and the second cell ID (Cell ID2) may be scanned in the eleventh to twentieth processes. In the first to tenth processes, which are some of the processes, the first cell ID (Cell ID1) may be scanned by irradiating light onto the front surface of the display panel DP, and in the eleventh to twentieth processes, which are some other of the processes, the second cell ID (Cell ID2) may be scanned by irradiating light onto the rear surface of the display panel DP. However, the processes during which the first cell ID (Cell ID1) and the second cell ID (Cell ID2) are scanned, and the direction light irradiated on the display panel DP are not limited thereto.

FIG. 8A and FIG. 8B shows that the display panel DP includes two cell IDs (Cell ID1 and Cell ID2), but the number of the cell IDs (Cell ID) is not limited to two, and three or more cell IDs (Cell ID) may be provided in the non-display area NDA of the display panel DP. In FIG. 8A, it is shown that the cell IDs (Cell ID1 and Cell ID2) are provided on the lower portion of the display panel DP in the non-display area NDA, but an area on which the cell ID (Cell ID) is provided in the non-display area NDA is not limited thereto. For example, the cell IDs (Cell ID1 and Cell ID2) may be provided on other areas within the non-display area NDA of the display panel DP.

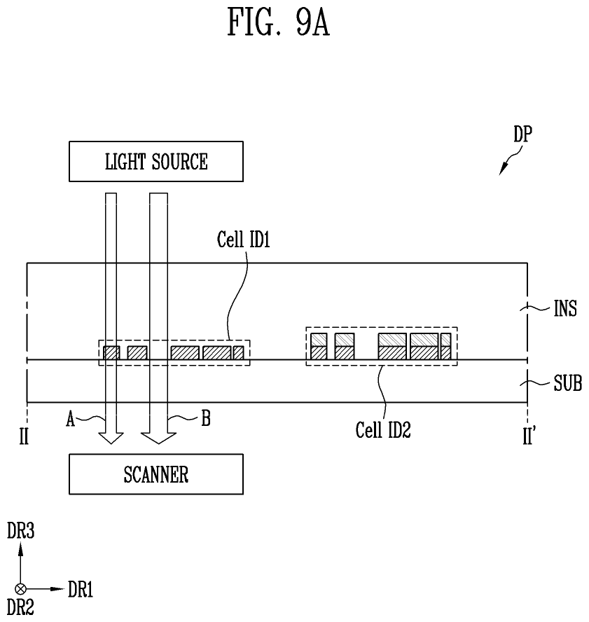

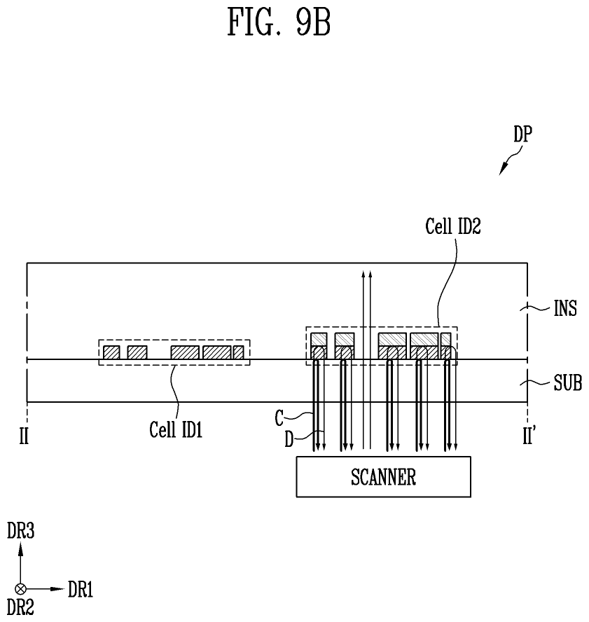

FIG. 9A is a schematic cross-sectional view illustrating a process in which a first cell ID (Cell ID1) is scanned in an embodiment.

Referring to FIG. 9A, the first cell ID (Cell ID1) may be a thin film layer having a single film structure provided on the substrate SUB. The first cell ID (Cell ID1) may be made of a semiconductor material, for example, polysilicon or amorphous silicon. The first cell ID (Cell ID1) may be patterned into a shape (for example, a barcode, a QR code, a character string, or a number sequence) corresponding to identification information of the display panel DP.

In an embodiment, A light (A) and B light (B) from a light source may be irradiated onto the upper surface of the display panel DP. The A light (A) may be irradiated onto an area in which the semiconductor pattern of the first cell ID (Cell ID1) is provided, and the B light (B) may be irradiated onto the area in which the semiconductor pattern of the first cell ID (Cell ID1) is not provided. A portion of the A light (A) irradiated onto the area in which the semiconductor pattern is provided may be reflected from the surface of the semiconductor pattern or absorbed by the semiconductor material. Accordingly, an intensity of the A light (A) passing through the display panel DP to reach the scanner may be less than an intensity of the B light (B) passing through the display panel DP to reach the scanner. As described above, based on the intensity of the light radiated onto the area in which the semiconductor pattern is provided and the intensity of the light radiated onto the area in which the semiconductor pattern is not provided, identification information of the display panel DP provided in a specific pattern on the substrate SUB may be read.

FIG. 9B is a schematic cross-sectional view illustrating a process in which a second cell ID (Cell ID2) is scanned in an embodiment.

In an embodiment, in a process in which scanning of the first cell ID (Cell ID1) is not readily performed among the processes of the display panel DP, the second cell ID (Cell ID2) may be scanned. For example, as the manufacturing process of the display panel DP progresses, in case that an organic material is formed with a certain thickness or more in the area in which the cell IDs (Cell ID1 and Cell ID2) are provided, an amount of light passing through the display panel DP and reaching the scanner may be small. Accordingly, the process of scanning the first cell ID (Cell ID1) may not be readily performed, and in case that the process of scanning of the first cell ID (Cell ID1) is not readily performed, the second cell ID (Cell ID2) may be scanned.

Referring to FIG. 9B, the second cell ID (Cell ID2) may have a stacked structure of thin film layers provided on the substrate SUB. The thin film layers included in the second cell ID (Cell ID2) may include a metallic material (in addition to a semiconductor material). The thin film layer including the metallic material may be provided on the thin film layer including the semiconductor material. The semiconductor material may be polysilicon, amorphous silicon, the like, or a combination thereof. The metallic material may include one of molybdenum (Mo), aluminum (Al), chromium (Cr), gold (Au), titanium (Ti), nickel (Ni), neodymium (Nd), copper (Cu), and the like. The metallic material may include an alloy of two or more metals of molybdenum (Mo), aluminum (Al), chromium (Cr), gold (Au), titanium (Ti), nickel (Ni), neodymium (Nd), copper (Cu), and the like. The second cell ID (Cell ID2) may be patterned into a shape (for example, a barcode, a QR code, a character string, or a number sequence) corresponding to identification information of the display panel DP. A shape of the second cell ID (Cell ID2) in a plan view and a shape of the first cell ID (Cell ID1) in a plan view may be the same.

In an embodiment, light from a light source (not shown) may be irradiated to the lower surface of the display panel DP. The light irradiated to an area in which the semiconductor and metal pattern is not provided may pass through the display panel DP, and a portion of the light irradiated to an area in which the semiconductor and metal pattern is provided may be reflected. Based on the light reflected from the semiconductor and metal pattern and reaching the scanner, the identification information of the display panel DP provided in a specific pattern on the substrate SUB may be read.

More light may pass through a semiconductor material, for example, a polysilicon or amorphous silicon thin film layer, than a metal thin film layer. In contrast, a metal thin film layer may reflect more light than a polysilicon or amorphous silicon thin film layer. Since the cell ID (Cell ID) in FIG. 7B is a thin film layer having a single film structure made of a semiconductor material, an amount of light reflected from the cell ID (Cell ID) may be small.

Referring to FIG. 9B, C light (C) may be reflected from the surface of the thin film layer including the semiconductor material, and D light (D) may pass through the thin film layer including the semiconductor material. The D light (D) passed through the thin film layer including the semiconductor material may be reflected from the surface of the thin film layer including a metallic material. Compared to the thin film layer of the single film structure made of a semiconductor material, the amount of light reflected from the second cell ID (Cell ID2) and reaching the scanner may increase, and accordingly, the recognition rate of the second cell ID (Cell ID2) may be improved.

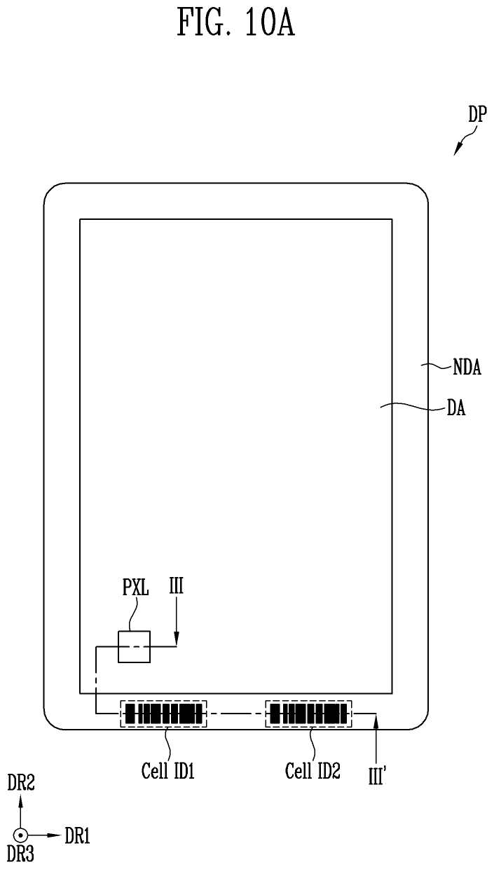

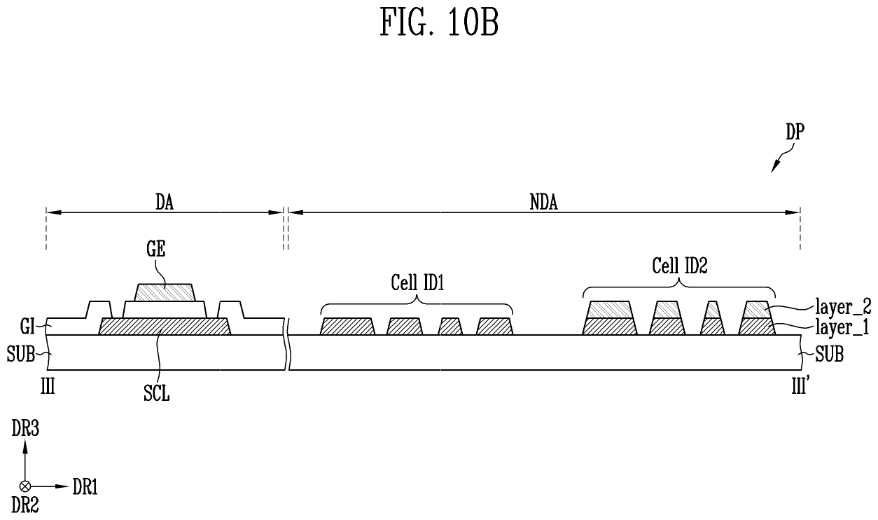

FIG. 10A and FIG. 10B are drawings illustrating a manufacturing process of a display panel DP according to an embodiment.

FIG. 10A is a schematic plan view of the display panel DP manufactured by manufacturing method of the display panel DP according to an embodiment, and FIG. 10B is a schematic cross-sectional view taken along line III-III′ of FIG. 10A.

Referring to FIG. 10A and FIG. 10B, the display panel DP may include pixels PXL in the display area DA, and multiple cell IDs (Cell ID1 and Cell ID2) in the non-display area NDA.

In an embodiment, the first cell ID (Cell ID1) and the second cell ID (Cell ID2) may be provided together on the substrate SUB in a process of providing (or forming) the pixels PXL in the display area DA.

The manufacturing process of the display panel DP may include providing (or forming) a pixel circuit layer PCL including a pixel circuit in the display area DA on the substrate SUB and providing a display element layer DPL on the pixel circuit layer PCL. The providing of the pixel circuit layer PCL, the providing of the display element layer DPL on the pixel circuit layer PCL, and the providing of the pixel circuit layer PCL and the display element layer DPL in FIG. 5 may be the same.

The providing of the pixel circuit layer PCL may include forming multiple transistors included in the pixel circuit. The transistors, and the first transistor T1 and the second transistor T2 in FIG. 5 may be the same. In the providing of the pixel circuit layer PCL, the semiconductor layer SCL of the pixel circuit may be provided on the substrate SUB. The gate insulating layer GI may be provided on the semiconductor layer SCL. The gate electrode GE of the pixel circuit and the source and drain electrodes SE and DE each contacting a partial area of the semiconductor layer SCL may be provided on the gate insulating layer GI. Each of the source and drain electrodes SE and DE may contact a partial area of the semiconductor layer SCL through a contact hole provided in the gate insulating layer GI.

The forming (or providing) of the display element layer DPL may include providing the anode electrode AE (or the first electrode AE) on the pixel circuit layer PCL, providing the light emitting layer EML (see, e.g., FIG. 5) in contact with the anode electrode AE, and providing the cathode electrode CE (or the second electrode CE, see, e.g., FIG. 5) on the light emitting layer EML.

The manufacturing process of the display panel DP may include providing the cell IDs (Cell ID1 and Cell ID2) indicating identification information for identifying the display panel DP in the non-display area NDA on the substrate SUB. The providing of the cell IDs (Cell ID1 and Cell ID2) may include providing the first cell ID (Cell ID1) in a portion of the non-display area NDA and providing the second cell ID (Cell ID2) in another portion of the non-display area NDA.

The first cell ID (Cell ID1) may have single film structure of a thin film layer, and the second cell ID (Cell ID2) may have a stacked structure of thin film layers. The thin film layer of the single film structure included in the first cell ID (Cell ID1) and the semiconductor layer SCL of the pixel circuit layer PCL may include a same material. The thin film layers of the stacked structure included in the second cell ID (Cell ID2) may include a first thin film layer (layer_1) and a second thin film layer (layer_2) including a metallic material. The first thin film layer (layer_1) and the semiconductor layer SCL may include a same material. The metallic material included in the second thin film layer (layer_2) and the material configuring the gate electrode GE of the pixel circuit layer PCL may be the same.

In an embodiment, the thin film layer of the single film structure included in the first cell ID (Cell ID1), the first thin film layer (layer_1) of the second cell ID (Cell ID2), and the semiconductor layer SCL of the pixel circuit may be provided simultaneously in a same process. The second thin film layer (layer_2) of the second cell ID (Cell ID2) and the gate electrode GE may be provided simultaneously in a same process.

Although not shown in FIG. 10B, after the gate electrode GE and the second thin film layer (layer_2) of the second cell ID (Cell ID2) are provided, an insulating layer may be provided on the first cell ID (Cell ID1) and the second cell ID (Cell ID2) in the non-display area NDA. The insulating layer provided on the first cell ID (Cell ID1) and the second cell ID (Cell ID2) and the interlayer insulating layer ILD (see, e.g., FIG. 5) or the passivation layer PSV (see, e.g., FIG. 5) provided in the display area DA may include a same material. The insulating layer provided on the first cell ID (Cell ID1) and the second cell ID (Cell ID2) may be provided together in the non-display area NDA when the interlayer insulating layer ILD (see, e.g., FIG. 5) or the passivation layer PSV (see, e.g., FIG. 5) is provided in the display area DA.

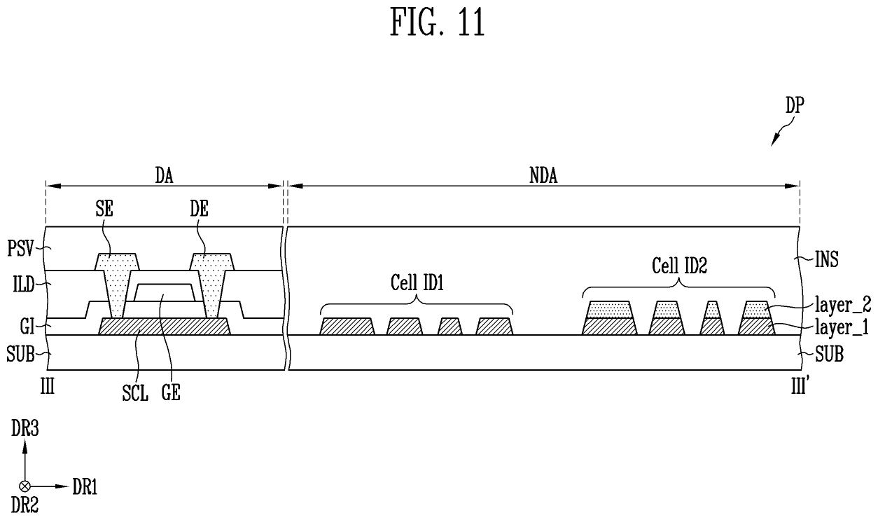

FIG. 11 is a schematic cross-sectional view illustrating a manufacturing process of a display panel DP according to another embodiment.

In FIG. 11, since the structures and manufacturing process orders of the pixel circuit layer PCL and the display element layer DPL provided in the display area DA and the first cell ID (Cell ID1) and the second cell ID (Cell ID2) provided in the non-display area NDA are the same, the description will focus on differences from the embodiment described in FIG. 10B.

Referring to FIG. 11, in the providing of the pixel circuit layer PCL, the semiconductor layer SCL of the pixel circuit, the gate insulating layer GI, and the gate electrode GE and the source and drain electrodes SE and DE of the pixel circuit may be provided on the substrate SUB. The passivation layer PSV may be provided on the source and drain electrodes SE and DE.

The first cell ID (Cell ID1) may be provided in a portion of the non-display area NDA on the substrate SUB, and the second cell ID (Cell ID2) may be provided in another portion of the non-display area NDA on the substrate SUB.

The first cell ID (Cell ID1) may have a single film structure including a thin film layer, and the second cell ID (Cell ID2) may have a stacked structure including thin film layers. The thin film layer of the single film structure included in the first cell ID (Cell ID1) and the semiconductor layer SCL of the pixel circuit layer PCL may include a same material. The thin film layers of the stacked structure included in the second cell ID (Cell ID2) may include a first thin film layer (layer_1) and a second thin film layer (layer_2) including a metallic material. The first thin film layer (layer_1) and the semiconductor layer SCL may include a same material.

Unlike the embodiment disclosed in FIG. 10B, in the embodiment disclosed in FIG. 11, the metallic material included in the second thin film layer (layer_2) and the material included in the source and drain electrodes SE and DE, rather than the gate electrode GE of the pixel circuit layer PCL, may be the same.

In an embodiment, the thin film layer of the single film structure included in the first cell ID (Cell ID1), the first thin film layer (layer_1) of the second cell ID (Cell ID2), and the semiconductor layer SCL of the pixel circuit may be provided simultaneously in a same process.

Unlike the embodiment disclosed in FIG. 10B, in the embodiment disclosed in FIG. 11, the second thin film layer (layer_2) of the second cell ID (Cell ID2) and the source and drain electrodes SE and DE rather than the gate electrode GE of the pixel circuit layer PCL may be provided at the same time in a same process.

After the source and drain electrodes SE and DE and the second thin film layer (layer_2) of the second cell ID (Cell ID2) are provided, the passivation layer PSV may be provided in the display area DA, and the insulating layer INS may be provided on the first cell ID (Cell ID1) and the second cell ID (Cell ID2) in the non-display area NDA. The insulating layer INS provided on the first cell ID (Cell ID1) and the second cell ID (Cell ID2) and the passivation layer PSV provided in the display area DA may include a same material. The insulating layer INS provided on the first cell ID (Cell ID1) and the second cell ID (Cell ID2) may be provided together in the non-display area NDA when the passivation layer PSV is provided in the display area DA.

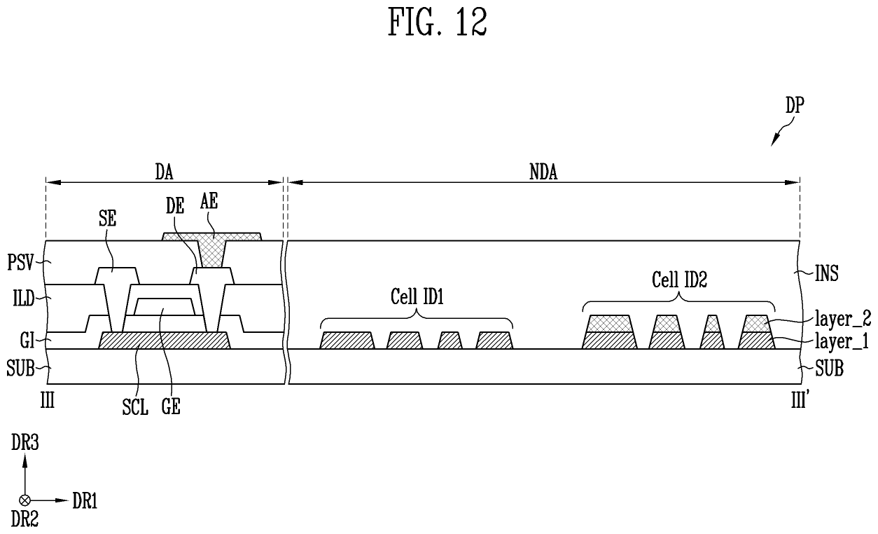

FIG. 12 is a schematic cross-sectional view illustrating a manufacturing process of a display panel DP according to another embodiment.

In FIG. 12, since the structures and manufacturing process orders of the pixel circuit layer PCL and the display element layer DPL provided in the display area DA and the first cell ID (Cell ID1) and the second cell ID (Cell ID2) provided in the non-display area NDA are the same, the description will focus on differences from the embodiment described in FIG. 10B.

Referring to FIG. 12, in the providing of the pixel circuit layer PCL, the semiconductor layer SCL of the pixel circuit, the gate insulating layer GI, and the gate electrode GE and the source and drain electrodes SE and DE of the pixel circuit may be provided on the substrate SUB. The passivation layer PSV may be provided on the source and drain electrodes SE and DE. The anode electrode AE of the display element may be provided on the passivation layer PSV. The anode electrode AE may contact the drain electrode DE through a contact hole penetrating the passivation layer PSV.

The first cell ID (Cell ID1) may be provided in a portion of the non-display area NDA on the substrate SUB, and the second cell ID (Cell ID2) may be provided in another portion of the non-display area NDA on the substrate SUB.

The first cell ID (Cell ID1) may have a single film structure including a thin film layer, and the second cell ID (Cell ID2) may have a stacked structure including thin film layers. The thin film layer of the single film structure included in the first cell ID (Cell ID1) and the semiconductor layer SCL of the pixel circuit layer PCL may include a same material. The thin film layers of the stacked structure included in the second cell ID (Cell ID2) may include a first thin film layer (layer_1) and a second thin film layer (layer_2) including the metallic material. The first thin film layer (layer_1) and the semiconductor layer SCL may include a same material.

Unlike the embodiment disclosed in FIG. 10B, in the embodiment disclosed in FIG. 12, the metallic material included in the second thin film layer (layer_2) and the material included in the anode electrode AE of the display element layer DPL, rather than the gate electrode GE of the pixel circuit layer PCL, may be the same.

In an embodiment, the thin film layer of the single film structure included in the first cell ID (Cell ID1), the first thin film layer (layer_1) of the second cell ID (Cell ID2), and the semiconductor layer SCL of the pixel circuit may be provided simultaneously in a same process.

Unlike the embodiment disclosed in FIG. 10B, in the embodiment disclosed in FIG. 12, the second thin film layer (layer_2) of the second cell ID (Cell ID2) and the anode electrode AE of the display element layer DPL rather than the gate electrode GE of the pixel circuit layer PCL may be provided at the same time in a same process.

After the anode electrode AE and the second thin film layer (layer_2) of the second cell ID (Cell ID2) are provided, the insulating layer INS may be provided on the first cell ID (Cell ID1) and the second cell ID (Cell ID2) in the non-display area NDA.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel including a display area and a non-display area, comprising:
cell IDs disposed on a substrate in the non-display area and indicating identification information for identifying the display panel; and
an insulating film disposed on the substrate and the cell IDs, wherein
the cell IDs include a first cell ID and a second cell ID disposed on the substrate in the non-display area,
the first cell ID and the second cell ID are disposed in different areas,
the first cell ID includes a single film structure including a first thin film layer, and
the second cell ID includes a stacked structure of second thin film layers.

2. The display panel of claim 1, wherein a material in the second thin film layers has a higher reflectance with respect to light than a material in the first thin film layer.

3. The display panel of claim 1, wherein at least one of the second thin film layers includes an opaque material.

4. The display panel of claim 1, further comprising:
a pixel circuit layer disposed on the substrate in the display area, wherein
the pixel circuit layer includes a pixel circuit including a gate electrode, a source electrode, a drain electrode, and a semiconductor layer,
the first thin film layer and the semiconductor layer include a same material,
the second thin film layers include a third thin film layer and a fourth thin film layer,
the third thin film layer and the semiconductor layer include a same material, and
the fourth thin film layer includes a metallic material.

5. The display panel of claim 4, wherein the fourth thin film layer is provided on the third thin film layer.

6. The display panel of claim 4, wherein
the semiconductor layer includes polysilicon or amorphous silicon, and
the fourth thin film layer includes molybdenum.

7. The display panel of claim 4, wherein the fourth thin film layer and the gate electrode include a same material.

8. The display panel of claim 4, wherein the fourth thin film layer, the source electrode, and the drain electrode include a same material.

9. The display panel of claim 1, further comprising:
a pixel circuit layer on the substrate in the display area; and
a display element layer disposed on the pixel circuit layer, wherein
the pixel circuit layer includes a pixel circuit including a gate electrode, a source electrode, a drain electrode, and a semiconductor layer,
the display element layer includes a light emitting element including an anode electrode, a cathode electrode, and a light emitting layer provided between the anode electrode and the cathode electrode,
the first thin film layer and the semiconductor layer include a same material,
the second thin film layers include a third thin film layer and a fourth thin film layer,
the third thin film layer and the semiconductor layer include a same material, and
the fourth thin film layer and the anode electrode include a same material.

10. The display panel of claim 9, wherein the fourth thin film layer and the anode electrode have a three-layer stacked structure of ITO/AG/ITO.

11. A manufacturing method of a display panel including a display area and a non-display area, comprising:
providing cell IDs indicating identification information for identifying the display panel on a substrate in the non-display area; and
providing an insulating film on the substrate and the cell IDs, wherein
the providing of the cell IDs includes:
providing a first cell ID on a portion of the substrate in the non-display area; and
providing a second cell ID on another portion of the substrate in the non-display area,
the first cell ID includes a single film structure including a first thin film layer, and
the second cell ID includes a stacked structure of second thin film layers.

12. The manufacturing method of the display panel of claim 11, wherein a material in the second thin film layers has a higher reflectance with respect to light than a material in the first thin film layer.

13. The manufacturing method of the display panel of claim 12, wherein at least one of the second thin film layers includes an opaque material.

14. The manufacturing method of the display panel of claim 11, further comprising:
providing a pixel circuit layer including a pixel circuit on the substrate in the display area, wherein
the providing of the pixel circuit layer includes:
providing a semiconductor layer on the substrate;
providing a gate electrode on the semiconductor layer; and
providing a source electrode and a drain electrode, each contacting a portion of
the semiconductor layer,
the first thin film layer and the semiconductor layer include a same material,
the second thin film layers include a third thin film layer and a fourth thin film layer,
the third thin film layer and the semiconductor layer include a same material, and
the fourth thin film layer includes a metallic material.

15. The manufacturing method of the display panel of claim 14, wherein the providing of the cell IDs includes providing the fourth thin film layer on the third thin film layer after simultaneously providing the first thin film layer and the third thin film layer.

16. The manufacturing method of the display panel of claim 14, wherein
the semiconductor layer includes polysilicon or amorphous silicon, and
the fourth thin film layer includes molybdenum.

17. The manufacturing method of the display panel of claim 15, wherein
the first thin film layer, the third thin film layer, and the semiconductor layer are simultaneously provided, and
the fourth thin film layer and the gate electrode are simultaneously provided.

18. The manufacturing method of the display panel of claim 15, wherein
the first thin film layer, the third thin film layer, and the semiconductor layer are simultaneously provided, and
the fourth thin film layer, the source electrode, and the drain electrode are simultaneously provided.

19. The manufacturing method of the display panel of claim 11, further comprising:
providing a pixel circuit layer including a pixel circuit on the substrate in the display area; and
providing a display element layer on the pixel circuit layer, wherein
the providing of the pixel circuit layer includes:
providing a semiconductor layer on the substrate;
providing a gate electrode on the semiconductor layer; and
providing a source electrode and a drain electrode, each contacting a portion of the semiconductor layer,
the providing of the display element layer includes:
providing an anode electrode on the pixel circuit layer;
providing a light emitting layer contacting the anode electrode; and
providing a cathode electrode on the light emitting layer,
the first thin film layer and the semiconductor layer includes a same material,
the second thin film layers include a third thin film layer and a fourth thin film layer,
the third thin film layer and the semiconductor layer include a same material, and
the fourth thin film layer includes a conductive material.

20. The manufacturing method of the display panel of claim 19, wherein
the first thin film layer, the third thin film layer, and the semiconductor layer are simultaneously provided, and
the fourth thin film layer and the anode electrode are simultaneously provided.
